(19) United States
(12) Patent Application Publication
(10) Pub. No.: US 2015/0327389 A1
(43) Pub. Date: Nov. 12, 2015

(54) CONNECTION INCLUDING FLANGE IN COOPERATION WITH RESILIENT MEMBER TO ENGAGE AND DISENGAGE REMOVABLE PRINTED CIRCUIT ASSEMBLY

(71) Applicant: Hewlett-Packard Development Company, L.P., Houston, TX (US)

(72) Inventor: Paul E Westphall, Tomball, TX (US)

(21) Appl. No.: 14/399,949

(22) PCT Filed: Aug. 17, 2012
(86) PCT No.: PCT/US2012/051377

§ 371 Date: Nov. 7, 2014

(51) Int. Cl. H05K 7/14; H05K 7/10; H05K 1/18

(52) U.S. Cl. CPC H05K 7/1417; H05K 1/18; H05K 7/10

(57) ABSTRACT

A connection apparatus to receive a removable printed circuit assembly includes a connector body and a first locking unit coupled to the connector body. The first locking unit may include a first outer locking member having a first channel, a first inner locking member movably disposed in the first channel, and a first resilient member. The first inner locking member may include a first flange to engage with the removable printed circuit assembly in an engaged position and disengage from the removable printed circuit assembly in a disengaged position. The first resilient member may be disposed in the first channel and in contact with the first outer locking member and the first inner locking member to enable movement of the first inner locking member between the engaged position and the disengaged position.

### BACKGROUND

Connection apparatuses in electronic devices such as servers, and the like, may receive removable printed circuit assembly such as dual in-line memory modules (DIMMs). The DIMMs may store data, programs, and/or the like. DIMMs may be removed, reinstalled, and/or replaced as desired.

### BRIEF DESCRIPTION OF THE DRAWINGS

Non-limiting examples of the present disclosure are described in the following description, read with reference to the figures attached hereto and do not limit the scope of the claims. In the figures, identical and similar structures, elements or parts thereof that appear in more than one figure are generally labeled with the same or similar references in the figures in which they appear. Dimensions of components and features illustrated in the figures are chosen primarily for convenience and clarity of presentation and are not necessarily to scale. Referring to the attached figures:

FIG. 1 is a block diagram illustrating a connection apparatus according to an example.

FIGS. 2A and 2B are side elevation views illustrating a connection apparatus in a disengaged position and an engaged position with a removable printed circuit assembly, respectively, according to examples.

FIG. 3A is a perspective view illustrating a first locking unit of the connection apparatus of FIG. 2B according to an example.

FIG. 3B is a cross-sectional view of the first locking unit of the connection apparatus of FIG. 3A in an engaged position with a removable printed circuit assembly according to an example.

FIGS. 4A and 4B are cross-sectional views illustrating the first locking unit of the connection apparatus of FIG. 3B disengaged from the removable printed circuit assembly according to examples.

FIG. 5A is a perspective view illustrating a second locking unit of the connection apparatus of FIG. 2B according to an example.

FIG. 5B is a cross-sectional view illustrating a second locking unit of the connection apparatus of FIG. 5A in an engaged position with a removable printed circuit assembly according to an example.

FIGS. 6A and 6B are cross-sectional views illustrating the second locking unit of the connection apparatus of FIG. 5B disengaged from the removable printed circuit assembly according to examples.

FIG. 7 is a block diagram illustrating a printed circuit assembly installation system according to an example.

### DETAILED DESCRIPTION

In the following detailed description, reference is made to the accompanying drawings which form a part hereof, and in which is depicted by way of illustration specific examples in which the present disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims.

Connection apparatuses in electronic devices such as servers, and the like, may receive removable printed circuit assemblies such as memory modules. A printed circuit assembly may be a board that holds chips and/or other electronic components. Such a board may include an edge portion having electrical contacts thereon to be removable coupled to corresponding electrical contacts of a respective connector. For example, connection apparatuses conforming to standards such as respective JEDEC standards may receive removable memory modules such as dual in-line memory modules (DIMMs), and the like. The connection apparatus may include a central portion including a slot, for example, with electrical contacts and/or keys, to receive corresponding electrical contacts of an edge portion of a respective DIMM. The connection apparatus may also include a set of latches that movable engage the DIMM upon insertion of a respective edge portion of the DIMM into the slot. The latches may include detain bumps to contact respective portions of the connection apparatus to provide resistance there between to maintain the respective latches in an installed position. At times, however, an unintended force or vibration may cause the latches to overcome the resistance provided between the detain bumps and respective portions of the connection apparatus. Consequently, the DIMM may unintentionally become unseated from or misaligned with the connection apparatus. Thus, the DIMM and/or data stored therein may be damaged and/or unavailable.

In some examples, a connection apparatus to receive a removable printed circuit assembly may include a connector body and a first locking unit coupled to the connector body. The first locking unit may include a first outer locking member having a first channel, a first inner locking member movably disposed in the first channel, and a first resilient member. The first inner locking member may include a first flange to engage the removable printed circuit assembly in an engaged position and disengage from the removable printed circuit assembly in a disengaged position. Further, the first resilient member may be disposed in the first channel and in contact with the first outer locking member and the first inner locking member. Additionally, the first resilient member may enable movement of the first inner locking member between the engaged position and the disengaged position. Further, in the engaged position, the first resilient member may provide an adequate force to urge and maintain the first flange against the removable printed circuit assembly in the engaged position. Thus, an unintended force or vibration to unintentionally unseat or misalign the removable printed circuit assembly with the connection apparatus and damage resulting thereto may be reduced.

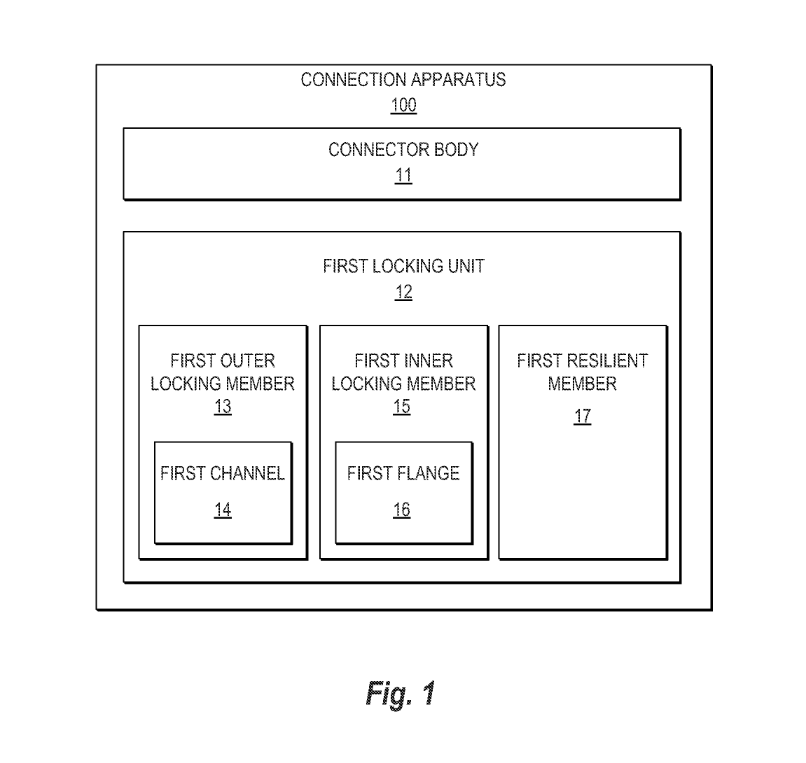

FIG. 1 is a block diagram illustrating a connection apparatus to receive a removable printed circuit assembly according to an example. Referring to FIG. 1, in some examples, the connection apparatus 100 may include a connector body 11 and a first locking unit 12 coupled to the connector body 11. The first locking unit 12 may include a first outer locking member 13 having a first channel 14, a first inner locking member 15 movably disposed in the first channel 14, and a first resilient member 17. The first inner locking member 15 may include a first flange 16 to engage with the removable printed circuit assembly in an engaged position and disengage from the removable printed circuit assembly in a disengaged position. The first resilient member 17 may be disposed in the first channel 14 and in contact with the first outer locking member 13 and the first inner locking member 15 to enable movement of the first inner locking member 15 between the engaged position and the disengaged position. That is, the first flange 16 and the first resilient member 17 may act in cooperation with each other to engage with, maintain sufficient force of engagement with, and disengage from the removable printed circuit assembly, when intended.

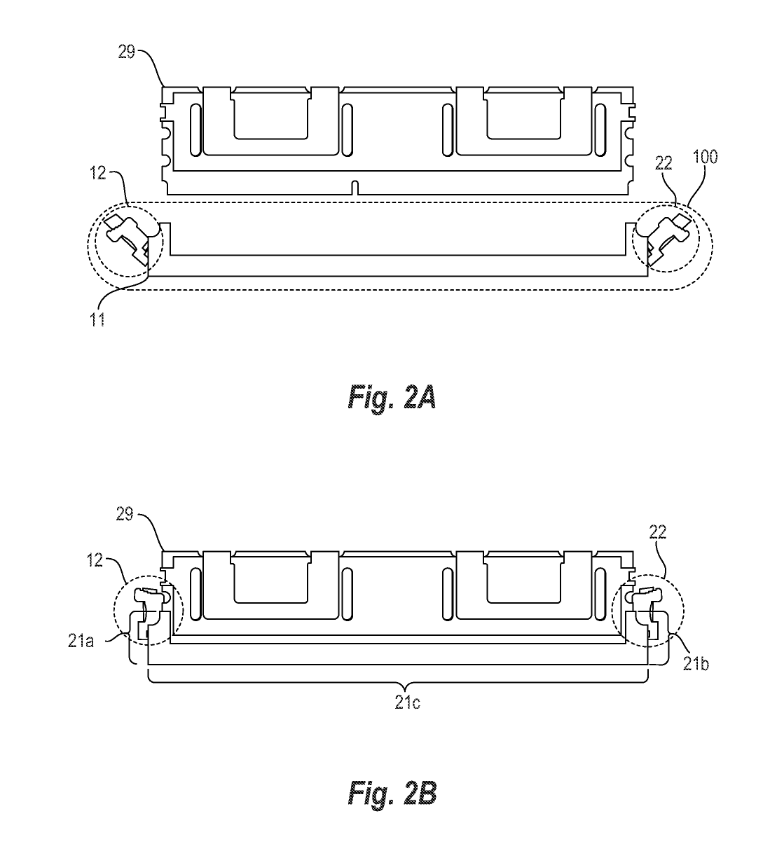

FIGS. 2A and 2B are side elevation views illustrating a connection apparatus in a disengaged position and an engaged position with a removable printed circuit assembly, respectively, according to examples. Referring to FIGS. 2A and 23, in some examples, the connector apparatus 100 includes a connector body 11, a first locking unit 12, and a second locking unit 22. The connector body 11 may include a first end portion 21a, a second end portion 21b, and a central portion 21c disposed between the first end portion 21a and the second end portion 21b. The first locking unit 12 may be moveably coupled at the first end portion 21a of the connector body 11. As illustrated in FIG. 2A, the first locking unit 12 and the second locking unit 22 may be placed in a disengaged position and rotated away from the removable printed circuit assembly 29, for example, to remove the removable printed circuit assembly 29 from the connector apparatus 100.

Referring to FIGS. 2A and 23, in some examples, the first locking unit 12 and the second locking unit 22 may manually rotate away from the removable printed circuit assembly 29 to allow removal of it from the central portion 21c of the connector body 11 of the connection apparatus 100. That is, a user may initiate movement of the first and second locking units 12 and 22 away from the removable printed circuit assembly 29 and subsequently, remove the printed circuit assembly 29 from the connector body 11. As illustrated in FIG. 2B, the removable printed circuit assembly 29 may be received by the connector apparatus 100. Also, the first locking unit 12 and the second locking unit 22 may be rotated toward the removable printed circuit assembly 29 and placed in an engaged position there with. In some examples, the first locking unit 12 and the second locking unit 22 may automatically rotate toward the removable printed circuit assembly 29 upon insertion of the printed circuit assembly 29 into the central portion 21c of the connector body 11 of the connection apparatus 100.

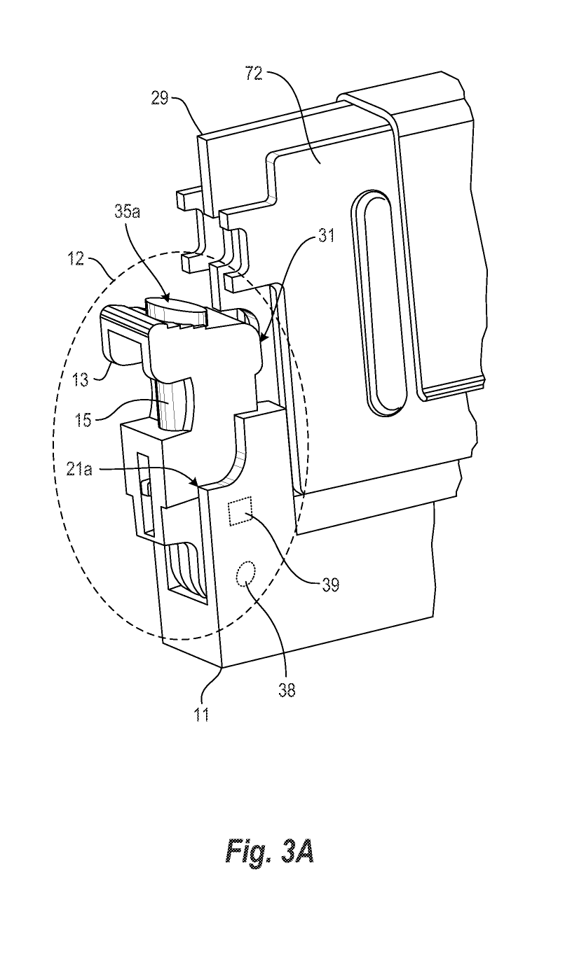

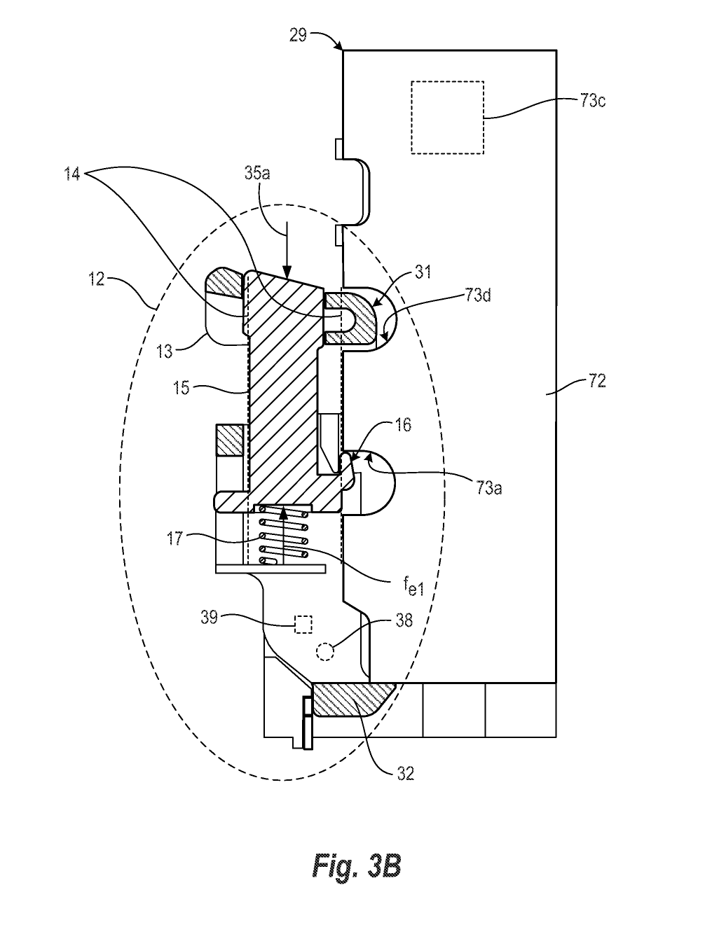

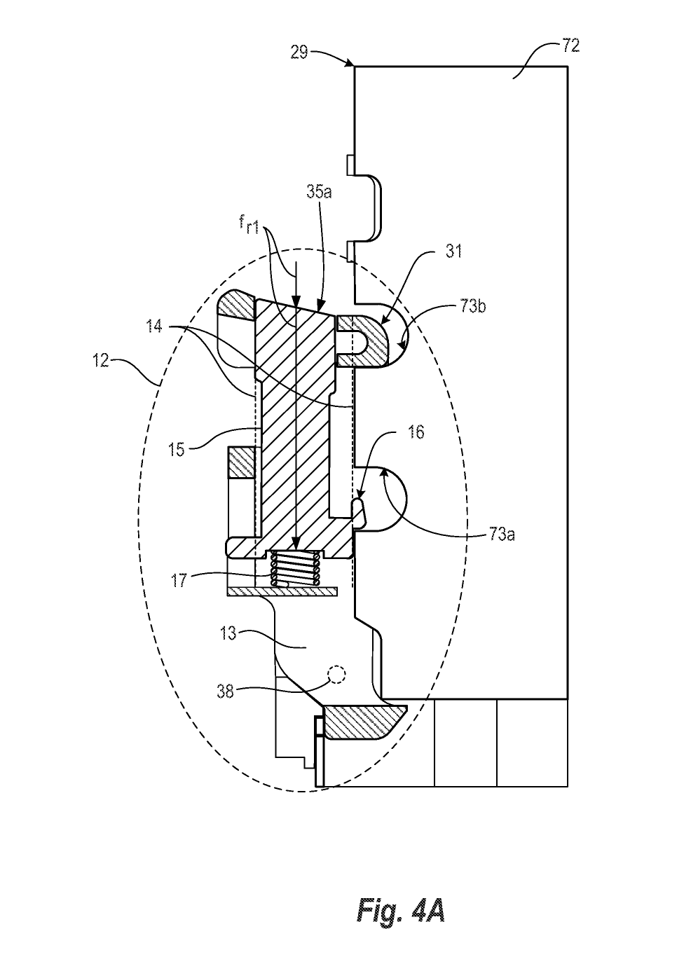

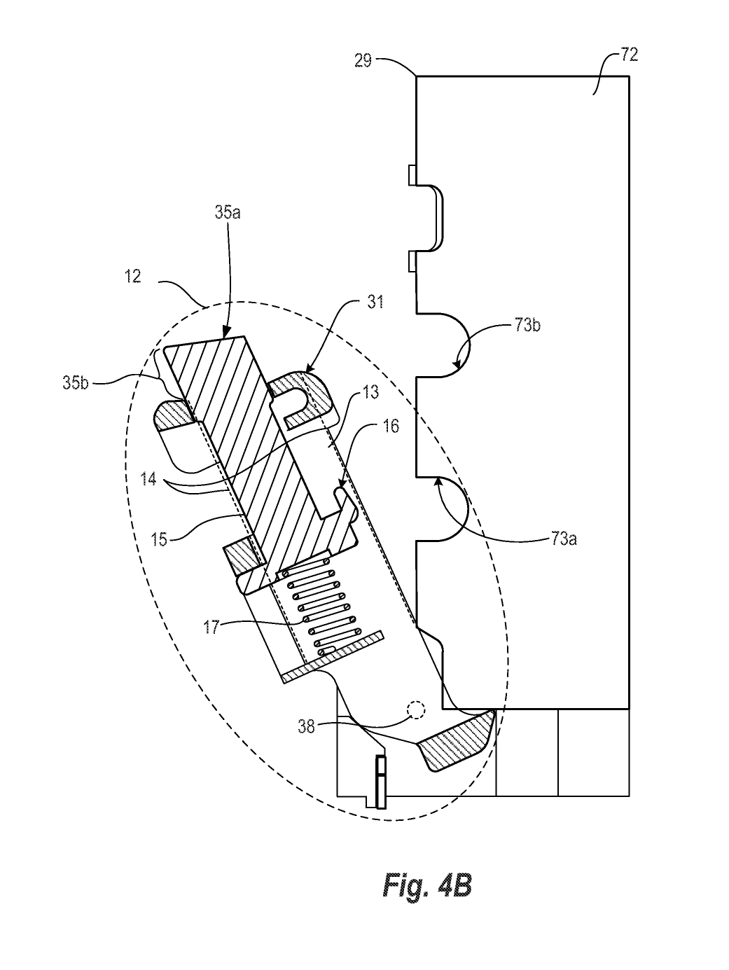

FIG. 3A is a perspective view illustrating a first locking unit of the connection apparatus of FIG. 2B according to an example. FIG. 3B is a cross-sectional view illustrating the first locking unit of the connection apparatus of FIG. 3A in an engaged position with a removable printed circuit assembly according to an example. FIGS. 4A and 4B are cross-sectional views illustrating the first locking unit of the connection apparatus of FIG. 3B disengaged from the removable printed circuit assembly according to examples. Referring to FIGS. 3A-4B, in some examples, the first locking unit 12 may include a first outer locking member 13 having a first channel 14, a first inner locking member 15 movably disposed in the first channel 14, a first resilient member 17, a first pivot member 38, and a first orientation member 32. The first channel 14 of the first outer locking member 13 may be disposed within and along a length of the first outer locking member 13.

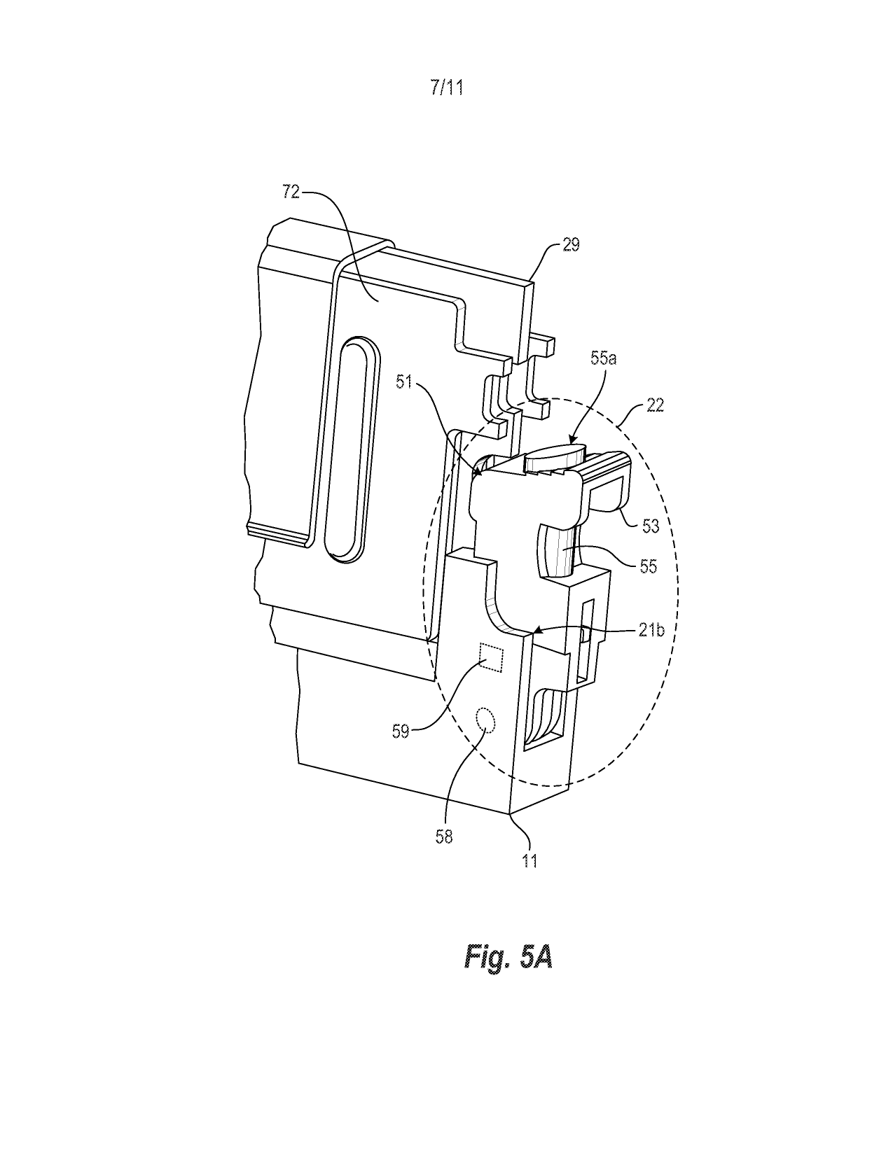

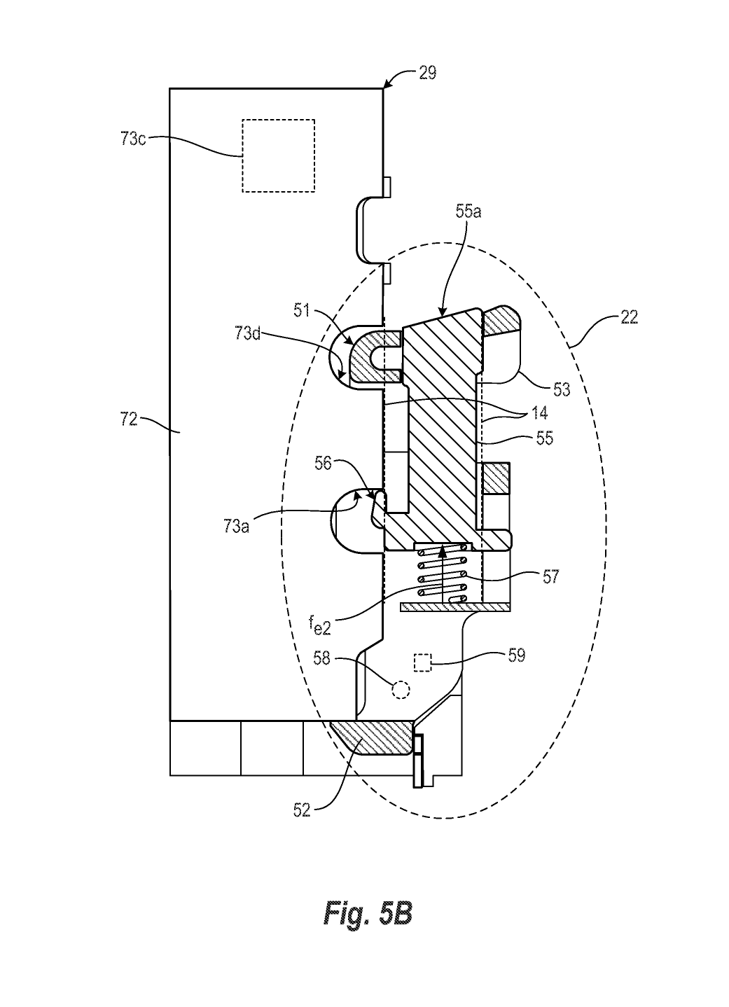

Referring to FIGS. 3A and 3B, in some examples, the first outer locking member 13 may also include a first detain bump 39 to engage a first end portion 21a of the connector body 11. In some examples, the first outer locking member 13 may include a plurality of first detain bumps 39. The first outer locking member 13 may also include a first protrusion 31 to interact with the removable printed circuit assembly 29. For example, the removable printed circuit assembly 29 may include a printed circuit board 72 having a first receiving indent 73a, a first supplemental indent 73d, a second receiving indent 73b (FIG. 5B), a second supplemental indent 73e (FIG. 5B), and a memory circuit 73c. In some examples, the first protrusion 31 may be placed proximate to the first supplemental indent 73d when the first locking unit 12 is rotated toward the printed circuit assembly 29.

Referring to FIGS. 3A-43, in some examples, the first inner locking member 15 may include a first flange 16, a first manual contact portion 35a, and a first indicator portion 35b. The first flange 16, for example, may extend outward from the first inner locking member 15. The first flange 16 may engage the removable printed circuit assembly 29 such as the first receiving indent 73a in an engaged position and disengage from the removable printed circuit assembly 29 such as the first receiving indent 73a in a disengaged position. For example, in the engaged position, the first flange 16 is urged against a portion of the first receiving indent 73a and in the disengage position the first flange 16 is moved apart from the respective portion of the first receiving indent 73a. For example, in the engaged position, an upper portion of the first flange 16 may be in contact with an upper portion of the first receiving indent 73a. Alternatively, in the disengaged position, the upper portion of the first flange 16 may move out of contact with an upper portion of the first receiving indent 73a.

The first manual contact portion 35a may be disposed at an end of the first inner locking member 15 to receive and transmit a first release force fᵣ₁ to the first resilient member 17 to place the first flange 16 in the disengaged position. In some examples, a position of the first indicator portion 35b with respect to the first outer locking member 13 may indicate whether the first locking unit 12 is in an engaged position or a disengaged position. That is, the first inner locking member 15 may extend outward from or, alternatively, be recessed within the first channel 14 when the first locking unit 12 is rotated toward the removable printed circuit assembly 29 and the first flange 16 is urged against the first receiving indent 73a to indicate that the first inner locking member 15 is in the engaged position.

Referring to FIGS. 3A-4B, in some examples, the first resilient member 17 may be disposed in the first channel 14 and in contact with the first outer locking member 13 and the first inner locking member 15 to enable movement of the first inner locking member 15 between the engaged position and the disengaged position. A first engaging force fₑ₁ of the first resilient member 17 may be configured to place the first flange 16 in the engaged position. That is, the first engaging force fₑ₁ may urge the first flange 16 against the respective portion of the first receiving indent 73a. For example, in the engaged position, the upper portion of the first flange 16 may be pressed in contact with the upper portion of the first receiving indent 73a.

Additionally, the first resilient member 17 may be configured to receive a first release force fᵣ₁ to place the first flange 16 in the disengaged position. For example, the first release force fᵣ₁ may be manually initiated by a user on the first manual contact portion 35a and transmitted to the first resilient member 17 to move the first flange 16 apart from the respective portion of the first receiving indent 73a. For example, in the disengaged position, the upper portion of the first flange 16 may move out of contact with an upper portion of the first receiving indent 73a. In some examples, the first resilient member 17 may be a spring member. The first pivot member 38 may movably couple the first locking unit 12 to the connector body 11 to enable the first locking unit 12 to rotate there about. In some examples, the first pivot member 38 may be a pin, a corresponding indent or detent, and the like. The first orientation member 32 may orient the first locking unit 12 with respect to the removable printed circuit assembly 29. For example, the first orientation member 32 may contact a portion of a respective printed circuit assembly 29 to assist in moving the first protrusion member 31 away from the first supplemental indent 73d during rotation of the first locking unit 12 away from the printed circuit assembly 29.

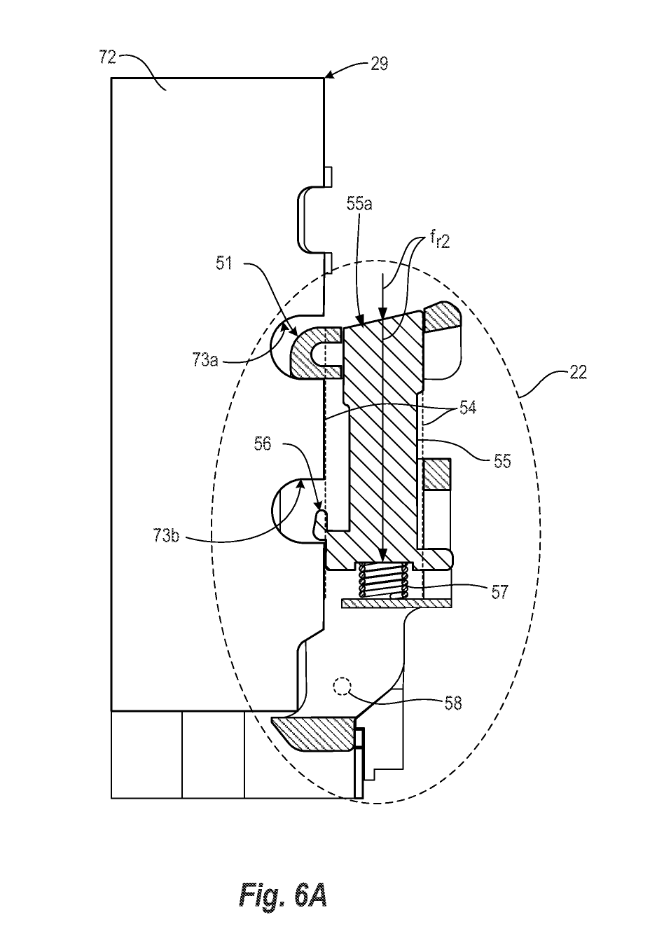

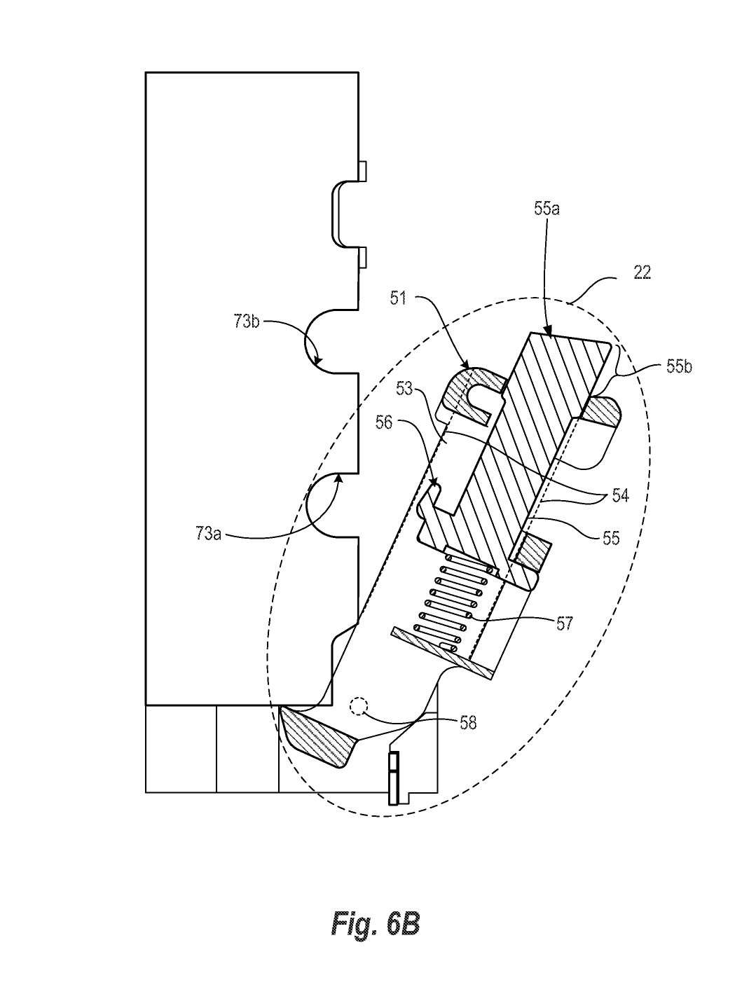

FIG. 5A is a perspective view illustrating a second locking unit of the connection apparatus of FIG. 2B according to an example. FIG. 5B is a cross-sectional view illustrating a second locking unit of the connection apparatus of FIG. 5A in an engaged position with a removable printed circuit assembly according to an example. FIGS. 6A and 6B are cross-sectional views illustrating the second locking unit of the connection apparatus of FIG. 5B disengaged from the removable printed circuit assembly according to examples. Referring to FIGS. 5A and 5B, in some examples, the second locking unit 22 may include a second outer locking member 53 having a second channel 54, a second inner locking member 55 movably disposed in the second channel 54, a second resilient member 57, a second pivot member 58, and a second orientation member 52. For example, the second channel 54 of the second outer locking member 53 may be disposed within and along a length of the second outer locking member 53.

The second outer locking member 53 may also include a second detain bump 59 to engage a second end portion 21b of the connector body 11. In some examples, the second outer locking member 53 may include a plurality of second detain bumps 59. The second outer locking member 53 may also include a second protrusion 51 to interact with the removable printed circuit assembly 29. For example, the removable printed circuit assembly 29 may include a printed circuit board 72 having a first receiving indent 73a (FIG. 3B), a first supplemental indent 73d (FIG. 3B), a second receiving indent 73b, a second supplemental indent 73e, and a memory circuit 73c. In some examples, the second protrusion 51 may be placed proximate to the second supplemental indent 73e when the second locking unit 22 is rotated toward the printed circuit assembly 29.

Referring to FIGS. 5A-6B, in some examples, the second inner locking member 55 may include a second flange 56, a second manual contact portion 55a, and a second indicator portion 55b. The second flange 56, for example, may extend outward from the second inner locking member 55. The second flange 56 may engage the removable printed circuit assembly 29 such as the second receiving indent 73b in an engaged position and disengage from the removable printed circuit assembly 29 such as the second receiving indent 73b in a disengaged position. For example, in the engaged position, the second flange 56 is urged against a portion of the second receiving indent 73b and in the disengage position the second flange 56 is moved apart from the respective portion of the second receiving indent 73b. For example, in the engaged position, an upper portion of the second flange 56 may be in contact with an upper portion of the second receiving indent 73b. Alternatively, in the disengaged position, the upper portion of the second flange 56 may move out of contact with an upper portion of the second receiving indent 73b.

The second manual contact portion 55a may be disposed at an end of the second inner locking member 55 to receive and transmit a second release force fᵣ₂ to the second resilient member 57 to place the second flange 56 in the disengaged position. In some examples, a position of the second indicator portion 55b with respect to the second outer locking member 53 may indicate whether the first locking unit 22 is in an engaged position or a disengaged position. That is, the second inner locking member 55 may extend outward from or, alternatively, be recessed within the second channel 54 when the second locking unit 22 is rotated toward the removable printed circuit assembly 29 and the second flange 56 is urged against the respective portion of the second receiving indent 73a to indicate that the second inner locking member 55 is in the engaged position.

Referring to FIGS. 5A-6B, in some examples, the second resilient member 57 may be disposed in the second channel 54 and in contact with the second outer locking member 53 and the second inner locking member 55 to enable movement of the second inner locking member 55 between the engaged position and the disengaged position. That is, the second flange 56 and the second resilient member 57 may act in cooperation with each other to engage with, maintain sufficient force of engagement with, and disengage from the removable printed circuit assembly 29, when intended. For example, a second engaging force fe₂ of the second resilient member 57 may be configured to place the second flange 56 in the engaged position. The second engaging force fₑ₂ may urge the second flange 56 against the respective portion of the second receiving indent 73b. For example, in the engaged position, the upper portion of the second flange 56 may be pressed in contact the upper portion of the second receiving indent 73b.

The second resilient member 57 may be configured to receive a second release force fᵣ₂ to place the second flange 56 in the disengaged position. That is, the second release force fᵣ₂ (FIG. 6A) may be manually initiated by a user on the second manual contact portion 55a and transmitted to the second resilient member 57 to move the second flange 56 apart from the respective portion of the second receiving indent 73b. For example, in the disengaged position, the upper portion of the second flange 56 may move out of contact with the upper portion of the second receiving indent 73b. In some examples, the second resilient member 17 may be a spring member. The second pivot member 58 may movably couple the second locking unit 22 to the connector body 11 to enable the second locking unit 22 to rotate there about. In some examples, the second pivot member 58 may be a pin, a corresponding detent or indent, and the like. The second orientation member 52 may orient the second locking unit 22 with respect to the removable printed circuit assembly 29. For example, the second orientation member 52 may contact a portion of a respective printed circuit assembly 29 to assist in moving the second protrusion member 51 away from the second supplemental indent 73e during rotation of the second locking unit 12 away from the printed circuit assembly 29.

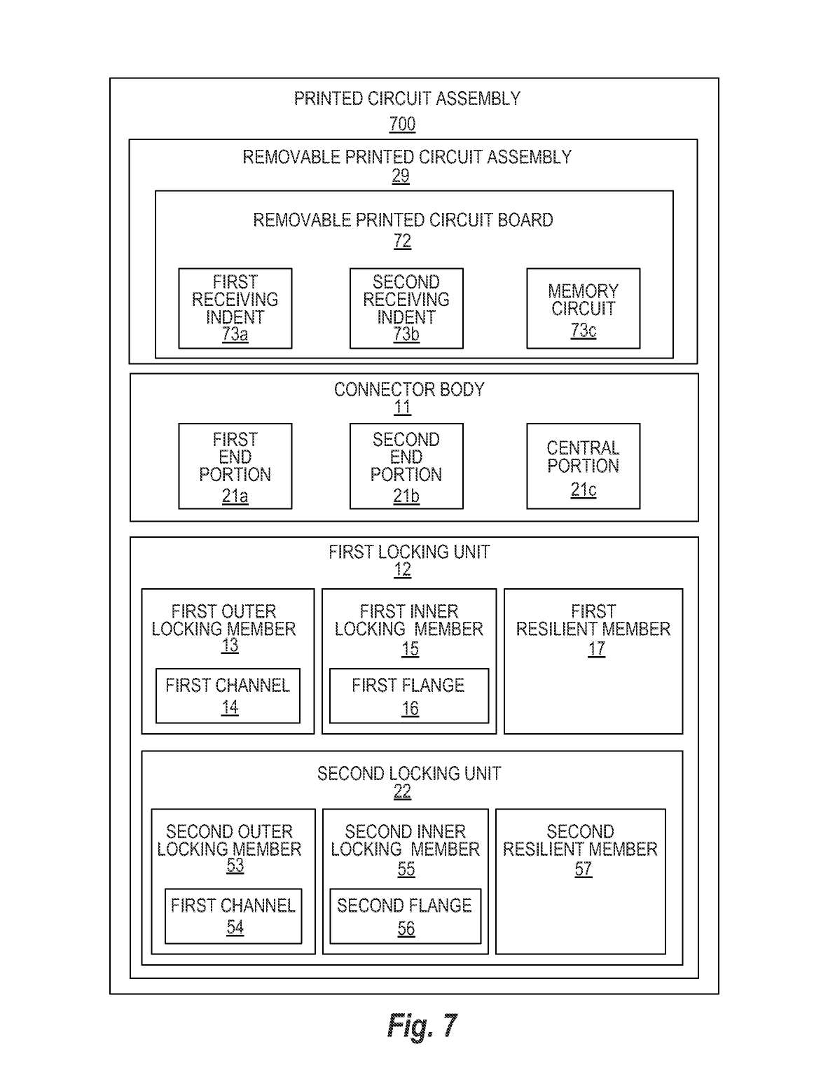

FIG. 7 is a block diagram illustrating a printed circuit assembly installation system according to an example. Referring to FIG. 7, in some examples, a printed circuit assembly installation system 700 may include a removable printed circuit assembly 29 and a connection apparatus 100. The removable printed circuit assembly 29 may include a printed circuit board 72. The printed circuit board 72 may include a first receiving indent 73a, a second receiving indent 73b, and a memory circuit 73c. The connection apparatus 100 to receive the removable printed circuit assembly 29 may include a connector body 11, a first locking unit 12, and a second locking unit 22. The connector body 11 may include a first end portion 21a, a second end portion 21b, and a central portion 21c disposed between the first end portion 21a and the second end portion 21b.

Referring to FIG. 7, in some examples, the first locking unit 12 may be movably coupled to the first end portion 21a of the connector body 11. The first locking unit 12 may include a first outer locking member 13 having a first channel 14, a first inner locking member 15 movably disposed in the first channel 14, and a first resilient member 17. The first inner locking member 15 may include a first flange 16 to engage a respective portion of the first receiving indent 73a in an engaged position and disengage from the respective portion of the first receiving indent 73a in a disengaged position. The first resilient member 17 may be disposed in the first channel 14 and in contact with the first outer locking member 13 and the first inner locking member 15 to enable movement of the first inner locking member 15 between the engaged position and the disengaged position.

Referring to FIG. 7, in some examples, the second locking unit 22 may be movably coupled to the second end portion 21b of the connector body 11. The second locking unit 22 may include a second outer locking member 53 having a second channel 54, a second inner locking member 55 movably disposed in the second channel 54, and a second resilient member 57. The second inner locking member 55 may include a second flange 56 to engage with a respective portion of the second receiving indent 73b in an engaged position and disengage from the respective portion of the second receiving indent 73b in a disengaged position. The second resilient member 57 may be disposed in the second channel 54 and in contact with the second outer locking member 53 and the second inner locking member 55 to enable movement of the second inner locking member 55 between the engaged position and the disengaged position. In some examples, the first resilient member 17 and the second resilient member 57 may be a spring member.

The present disclosure has been described using non-limiting detailed descriptions of examples thereof that are not intended to limit the scope of the present disclosure. It should be understood that features and/or operations described with respect to one example may be used with other examples and that not all examples have all of the features and/or operations illustrated in a particular figure or described with respect to one of the examples. Variations of examples described will occur to persons of the art. Furthermore, the terms “comprise,” “include,” “have” and their conjugates, shall mean, when used in the disclosure and/or claims, “including but not necessarily limited to.”

It is noted that some of the above described examples may include structure, acts or details of structures and acts that may not be essential to the present disclosure and which are described for illustrative purposes. Structure and acts described herein are replaceable by equivalents, which perform the same function, even if the structure or acts are different, as known in the art. Therefore, the scope of the present disclosure is limited only by the elements and limitations as used in the claims.

What is claimed is:

1. A connection apparatus to receive a removable printed circuit assembly, the connection apparatus comprising:
a connector body; and
a first locking unit coupled to the connector body, the first locking unit including a first outer locking member having a first channel, a first inner locking member movably disposed in the first channel, and a first resilient member;
the first inner locking member including a first flange to engage with the removable printed circuit assembly in an engaged position and disengage from the removable printed circuit assembly in a disengaged position; and
the first resilient member disposed in the first channel and in contact with the first outer locking member and the first inner locking member to enable movement of the first inner locking member between the engaged position and the disengaged position.

2. The connection apparatus according to claim 1, wherein a first engaging force of the first resilient member is configured to place the first flange in the engaged position.

3. The connection apparatus according to claim 2, wherein the first resilient member is configured to receive a first release force to place the first flange in the disengaged position.

4. The connection apparatus according to claim 3, wherein the first resilient member is a spring member.

5. The connection apparatus according to claim 1, wherein the first locking unit further comprises:
a first pivot member movably coupling the first locking unit to the connector body to enable the first locking unit to rotate there about.

6. The connection apparatus according to claim 1, wherein the connector body further comprises:
a first end portion, a second end portion, and a central portion disposed between the first end portion and the second end portion; and
wherein the first locking unit is moveably coupled at the first end portion of the connector body.

7. The connection apparatus according to claim 1, wherein the first inner locking member further comprises:
a first manual contact portion disposed at an end of the first inner locking member to receive and transmit a first release force to the first resilient member to place the first flange in the disengaged position.

8. The connection apparatus according to claim 6, wherein the first outer locking member includes a first detain bump to engage a first end portion of the connector body.

9. The connection apparatus according to claim 6, further comprising:
a second locking unit movably coupled to the second end portion of the connector body, the second locking unit including a second outer locking member having a second channel, a second inner locking member movably disposed in the second channel, and a second resilient member;
the second inner locking member including a second flange extending there from to engage with the removable printed circuit assembly in an engaged position and disengage from the removable printed circuit assembly in a disengaged position; and
the second resilient member disposed in the second channel and in contact with the second outer locking member and the second inner locking member to enable movement of the second inner locking member between the engaged position and the disengaged position.

10. The connection apparatus according to claim 9, wherein a second engaging force of the second resilient member is configured to place the second flange in the engaged position and the second resilient member is configured to receive a second release force to place the second flange in the disengaged position.

11. The connection apparatus according to claim 10, wherein the second resilient member is a spring member.

12. The connection apparatus according to claim 9, wherein the second locking unit further comprises:
a second pivot member movably coupling the second locking unit to the connector body to enable the second locking unit to rotate there about.

13. The connection apparatus according to claim 9, wherein the second inner locking member further comprises:
a second manual contact portion disposed at an end of the second inner locking member is configured to receive and transmit the second release force to the second resilient member to place the second flange in the disengaged position.

14. The connection apparatus according to claim 6, wherein the second outer locking member includes a second detain bump to engage a second end of the connector body.

15. A printed circuit assembly installation system, comprising:
a removable printed circuit assembly including a printed circuit board, the printed circuit board including a first receiving indent, a second receiving indent, and a memory circuit; and
a connection apparatus to receive the removable printed circuit assembly, the connection apparatus comprising:
a connector body including a first end portion, a second end portion, and a central portion disposed between the first end portion and the second end portion;
a first locking unit movably coupled to the first end portion of the connector body, the first locking unit including a first outer locking member having a first channel, a first inner locking member movably disposed in the first channel, and a first resilient member;
the first inner locking member including a first flange to engage with the a respective portion of the first receiving indent in an engaged position and disengage from the respective portion of the first receiving indent in a disengaged position; and
the first resilient member disposed in the first channel and in contact with the first outer locking member and the first inner locking member to enable movement of the first inner locking member between the engaged position and the disengaged position; and
a second locking unit movably coupled to the second end portion of the connector body, the second locking unit including a second outer locking member having a second channel, a second inner locking member movably disposed in the second channel, and a second resilient member;
the second inner locking member including a second flange to engage with a respective portion of the second receiving indent in an engaged position and disengage from the respective portion of the second receiving indent in a disengaged position; and
the second resilient member disposed in the second channel and in contact with the second outer locking member and the second inner locking member to enable movement of the second inner locking member between the engaged position and the disengaged position.
